(19) United States
(12) Patent Application Publication
(10) Pub. No.: US 2008/0012552 A1
(43) Pub. Date: Jan. 17, 2008

(54) Calibration device in magnetic sensor for inducting magnetic scale

(75) Inventor: Chih-Mao Shiao, Taichung (TW)

Correspondence Address: CHARLES E. BAXLEY, ESQ., 90 JOHN STREET, THIRD FLOOR, NEW YORK, NY, 10038, US

(73) Assignee: Hiwin Mikrosystem Corp.

(21) Appl. No.: 11/485,671

(22) Filed: Jul. 13, 2006

(51) Int. Cl. G01R 35/00

(52) U.S. Cl. 324/202

(57) ABSTRACT

The disclosed invention is a calibration device in magnetic sensor for inducting a magnetic scale which primarily comprises: a sensor unit which includes a Hall sensor to produce square signals when detecting the magnetic field generated by a magnetic scale; a signal display unit for presenting signals from said sensor unit; and signal display unit which has a display component for reflecting signal status of the sensor unit, and a signal output unit to transfer signals produced by the sensor unit into a set of Z and /Z signals for the measuring usage of the machine tool. By using this calibration device, a magnetic sensor produces signals to indicate an optimum clearance between a magnetic sensor and a magnetic scale whereon and presents this indication through the display unit to enable an operator to install the magnetic sensor correctly and promptly.

### BACKGROUND OF THE INVENTION

1. Technical Field

The present invention is related to a magnetic sensor for detecting a magnetic field generated by a magnetic scale and more particularly, to a calibration device provided in a magnetic sensor equipped with a display unit for indicating optimum clearance between the sensor and scale as well as outputting signals as a reference points.

2. Description of Related Art

Conventionally, methods for installing a magnetic sensor for inducting a magnetic scale can generally divided into following ways:

1. Installation relied on visual survey: By using this method, there is no auxiliary required. However, the result of installation is substantially subject to the operator's technical skill and visual accuracy. It may need repeated adjustments and amendments to obtain the optimum clearance between the magnetic sensor and the magnetic scale.

2. Installation relied on a ruler: A ruler may be also used to assist in installing the magnetic sensor and it indeed indicates a preset clearance accurately. Yet, by using this method, installation can be protracted and inconvenient. In particular, when the surroundings around the machine tool are cramped, the measurement can be difficult.

3. Installation relied on a special jig: It is helpful to utilize a jig, such as a spacer, when installing the magnetic sensor. Nevertheless, such a jig should be specializedly made for each machine tool and that unavoidably increases the costs in a significant way.

### SUMMARY OF THE INVENTION

The present invention has been accomplished under the circumstances in view.

It is one object of the present invention to provide a calibration device in a magnetic sensor for inducting a magnetic scale, which utilizes a sensor unit comprising a Hall sensor to detect the magnetic field. When the magnetic sensor is approaching the scale in a direction perpendicular to the surface of the scale,

and inducting the magnetic field generated by the scale, the Hall sensor outputs a signal to make a display component thereof change its appearance so that the operator may correctly install the sensor at an optimum position accordingly. Further, said display component may be a LED component. As the sensor moving along the surface of the scale width ways within the magnetic field of the scale, the LED component twinkles with the alternation between NR polarities it detects to inform the operator of normal operation.

It is a further object of the present invention to provide a calibration device in a magnetic sensor for inducting a magnetic scale, which has a signal output unit including a bipolar op amplifier to transfer the output signal form said sensor unit into a set of Z and /Z signals as a reference point for reposition of the machine tool.

The technical measures taken by the invention to achieve foregoing purpose and effect are given below:

a calibration device in a magnetic sensor for inducting a magnetic scale primarily comprising:

a sensor unit which includes a Hall sensor to produce square signals when detecting the magnetic field generated by a magnetic scale;

a signal display unit for presenting signal status of said sensor unit; and

a signal output unit for transferring signals from said sensor unit into a set of Z and /Z signals for measuring usage of the machine tool.

### BRIEF DESCRIPTION OF THE DRAWINGS

FIG. 1 is a block diagram illustrating the structure of the disclosed subject matter;

FIG. 2 is a circuit diagram according to the present invention;

FIG. 3 is a schematic view of signals generated by the units of the present invention.

FIG. 4 is a schematic drawing showing the installation of the disclosed subject matter; and

FIG. 5 is another schematic drawing showing the installation of the disclosed subject matter.

### DETAILED DESCRIPTION OF THE INVENTION

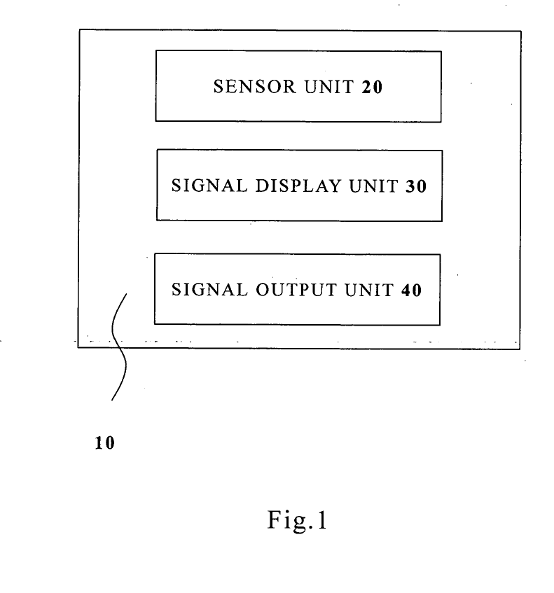

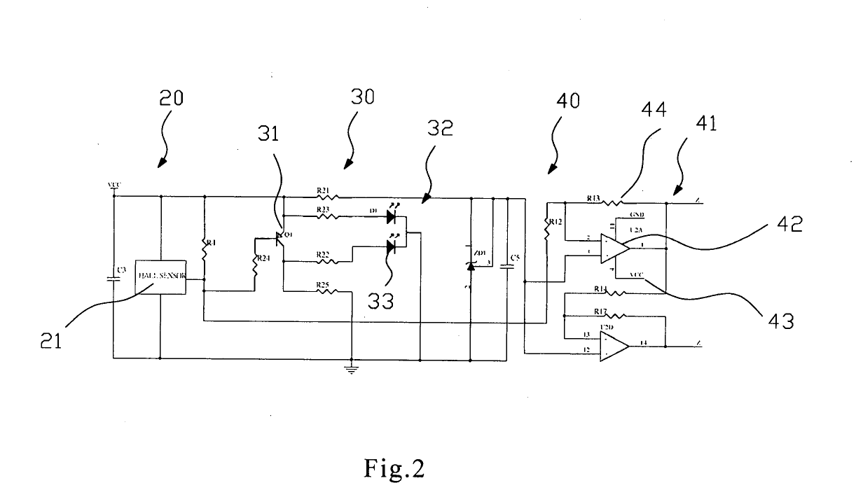

As shown in FIGS. 1 and 2, a calibration device in a magnetic sensor 10 for inducting a magnetic scale according to the present invention comprises:

a sensor unit 20 including a Hall sensor 21 which inducts a magnetic field and produces square signals on the principle of Hall effect, wherein the Hall sensor 21 produces “Hi” signals when it inducts a magnetic pole N while produces “Low” signals when it inducts a magnetic pole S;

a signal display unit 30 which includes an amplifying transistor 31 for transmitting signals generated by said sensor unit 20 to a display component 32 and driving the display component 32 to reflect the alternation of the signals; wherein the display component 32 is at least one LED component which is darkened when sensor unit 20 produces “Hi” signals and is brightened when sensor unit 20 produces “Low” signals; and

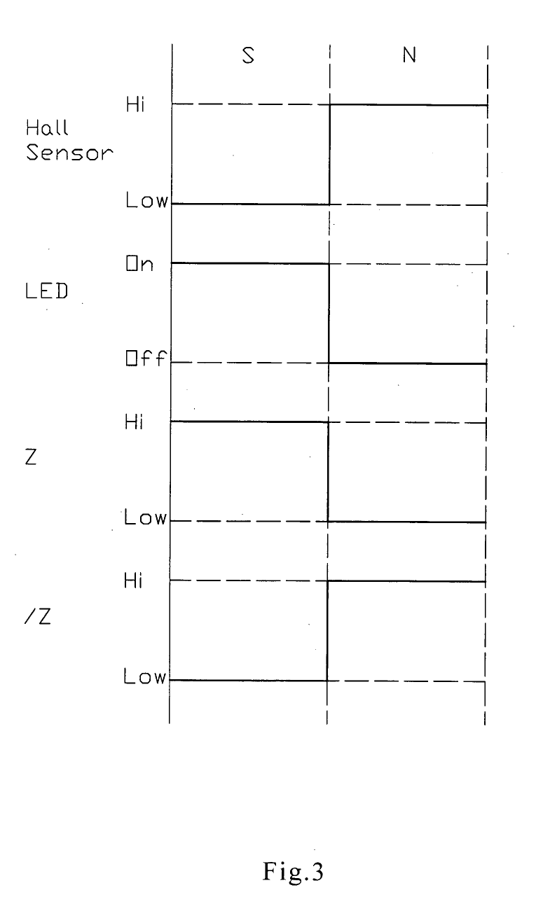

a signal output unit 40 having a bipolar op amplifier 41 which comprises an op amplifier 42, a power source 43 with reference voltage and a amplifying resistance 44 for transferring signals from said sensor unit 20 into a set of Z and /Z signals for measuring usage of the machine tool. As shown in FIG. 3, when sensor unit 20 produces a “Hi” signal, the corresponding Z signal is “Low” while the /Z signal is “Hi” and contrarily, when sensor unit 20 produces a “Low” signal, the corresponding Z signal is “Hi” while the /Z signal is “Low”

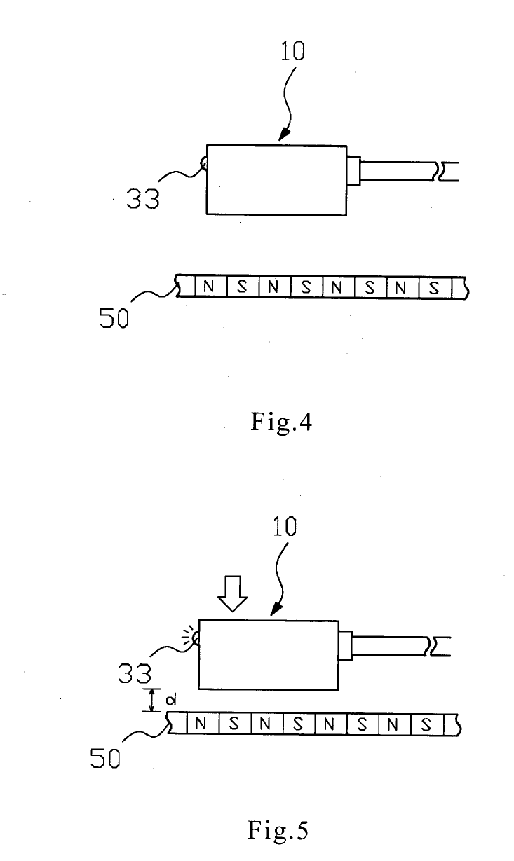

Referring to FIG. 4, since the Hall sensor 21 of the sensor unit 20 inducts the magnetic field by Hall effects, when an operator starts to install the magnetic sensor 10, he just needs to perpendicularly approach the magnetic sensor 10 toward the scale 50 from far. In FIG. 5, once the magnetic sensor 10 detects the magnetic file of the scale 50, it generates corresponding square signals. The signals are further transmitted to the display component 32 by the amplifying transistor 31 and the display component 32 changes it appearance to inform the operator that the magnetic sensor 10 is now arriving a correct installing position.

Moreover, since the LED component 33 is darkened when sensor unit 20 produces “Low” signals and is brightened when sensor unit 20 produces “Hi” signals, as the sensor 10 moves along the surface of the scale 50 widthways within the magnetic field of the scale 50, the LED component 33 twinkles corresponding to the alternation between NS polarities of the scale 50 it detects. Thus, an operator can confirm that the magnetic sensor 10 works normally.

Although a particular embodiment of the invention has been described in detail for purposes of illustration, it will be understood by one of ordinary skill in the art that numerous variations will be possible to the disclosed embodiments without going outside the scope of the invention as disclosed in the claims.

What the invention claimed is:

1. a calibration device in a magnetic sensor for inducting a magnetic scale primarily comprises:
a sensor unit which includes a Hall sensor to generate square signals when inducting the magnetic field generated by a magnetic scale;
a signal display unit having a display component for presenting signal status of said sensor unit; and
a signal output unit for transferring signals from said sensor unit into a set of Z and /Z signals for measuring usage of a machine tool where the device installed.

2. The calibration device in a magnetic sensor for inducting a magnetic scale as claimed in claim 1, wherein the Hall sensor produces “Hi” signal when inducting a magnetic pole N while produces “Low” signals when inducting a magnetic pole S.

3. The calibration device in a magnetic sensor for inducting a magnetic scale as claimed in claim 1, wherein the display unit comprises an amplifying transistor for transmitting signals from said sensor unit to the display component and driving the display component to reflect the alternation of the signals.

4. The calibration device in a magnetic sensor for inducting a magnetic scale as claimed in claim 1, wherein the display component is a LCD component.

5. The calibration device in a magnetic sensor for inducting a magnetic scale as claimed in claim 4, wherein the LED component is darkened when sensor unit produces “Hi” signals and is brightened when sensor unit produces “Low” signals.

6. The calibration device in a magnetic sensor for inducting a magnetic scale as claimed in claim 1, wherein the signal output unit comprises a bipolar op amplifier.

7. The calibration device in a magnetic sensor for inducting a magnetic scale as claimed in claim 1, wherein the bipolar op amplifier further comprises an op amplifier, a power source with reference voltage and an amplifying resistance.
